(19) United States
(12) Patent Application Publication
(10) Pub. No.: US 2016/0329439 A1
(43) Pub. Date: Nov. 10, 2016

(54) PHOTOVOLTAIC DEVICES WITH FINE-LINE METALLIZATION AND METHODS FOR MANUFACTURE

(71) Applicant: TetraSun, Inc., San Jose, CA (US)

(72) Inventors: Adrian Bruce TURNER, Palo Alto, CA (US); Bonneville Dudgeon EGGLESTON, Penang (MY)

(21) Appl. No.: 14/707,725

(22) Filed: May 8, 2015

(51) Int. Cl. H01L 31/02

(52) U.S. Cl. CPC H01L 31/0201

(57) ABSTRACT

A method for use in forming a photovoltaic device includes forming a doped semiconductor layer on a surface of a semiconductor substrate and forming a metal film on the doped semiconductor layer. A patterned etched resist is formed on the metal film and the resist includes a plurality of finger portions and a plurality of bus bar portions aligned in a grid pattern. A metal film is etched to form a pattern of fingers and bus bars according to the resist.

### RELATED APPLICATION INFORMATION

This Application is related to U.S. patent application Ser. No. 13/265,462, filed Nov. 15, 2011 (Attorney Docket No. 3304.001A); U.S. patent application Ser. No. 13/637,176, filed Sep. 25, 2012 (Attorney Docket No. 3304.008A); U.S. Pat. No. 8,236,604, filed Feb. 15, 2011 (Attorney Docket No. 3304.010A); U.S. Patent Application No. 61/589,459, filed on Jan. 23, 2012 (Attorney Docket No. 3304.011(P)); U.S. Ser. No. 14/373,938, filed Jul. 23, 2014 (Attorney Docket No. 3304.011A); U.S. Provisional Patent Application No. 61/657,098, filed Jun. 8, 2012 (Attorney Docket No. 3304.012(P)); U.S. Ser. No. 61/718,489, filed Oct. 25, 2012 (Attorney Docket No. 3304.013(P)); PCT International Application No. PCT/US2013/066532 filed on Oct. 24, 2013 (Attorney Docket No. 3304.013AWO), and U.S. patent application Ser. No. 14/707,697, filed on May 8, 2015, (Attorney Docket No. 3304.016), which are incorporated herein by reference in their entirety.

### FIELD OF THE INVENTION

Disclosed embodiments generally relate to photovoltaic devices which include solar cells and solar modules containing solar cells. More particularly, the disclosed embodiments relate to improved solar cell structures and methods of manufacture for increased cell efficiency.

### BACKGROUND

Photovoltaic devices convert photons from incident sunlight into useable electric energy, for example using semiconductor materials deposited over a substrate. The semiconductor layer(s) may be made of an n-type semiconductor material and a p-type semiconductor material. The interaction of an n-type or p-type semiconductor layer with a semiconductor layer of the opposite type creates a p-n junction which facilitates movement of electrons and holes created from absorbed photons via the photovoltaic effect, to produce electric current.

Improved efficiency for photovoltaic conversion, and greater electrical output from solar cells/modules, are desired characteristics of photovoltaic devices.

Accordingly, a need for a high-efficiency photovoltaic device and a method of manufacture arises.

### SUMMARY OF THE INVENTION

The present invention provides, in a first aspect, a method for use in forming a photovoltaic device which includes forming a doped semiconductor layer on a surface of a semiconductor substrate and forming a metal film on the doped semiconductor layer. A patterned etch-resist is formed on the metal film and the resist includes a plurality of finger portions and a plurality of bus bar portions aligned in a grid pattern. A metal film is etched to form a pattern of fingers and bus bars according to the resist.

### BRIEF DESCRIPTION OF THE DRAWINGS

FIG. 1 is a schematic, partial cross-sectional view of a solar cell, with an optimized front contact structure for a high-efficiency solar cell;

FIG. 2 shows that a metal contact line may be used as a seed layer to start plating an electrode to a desired thickness;

FIGS. 3-11 are schematic, partial cross-sectional views of a solar cell showing an example embodiment of the invention in which a metal etch resist is used to form a metal grid pattern for e.g., a solar cell, as follows:

FIG. 3 shows the metal contact deposited on a substrate of the cell;

FIG. 4 shows a narrow resist dispensed over the metal film of the cell;

FIGS. 5A-5G show various grid patterns of resists and bus bars in accordance with the present invention;

FIG. 6 shows the metal contact etched except for a portion thereof covered by a resist;

FIG. 7 shows a single, dual-function passivation/antireflection layer formed over the cell of FIGS. 5A-5G;

FIG. 8 shows an electrical contact formed on the remaining metal contact;

FIG. 9 shows an embodiment of a manufacturing process for forming the device of FIGS. 1-8 and 10, in flowchart form;

FIG. 10 is a planar view showing an example of an electrode configuration; and

FIG. 11 is a planar view showing a plurality of resist lines of a bus bar resist parallel to a plurality of finger resist portions prior to perpendicular resist lines of the bus bar resist being applied.

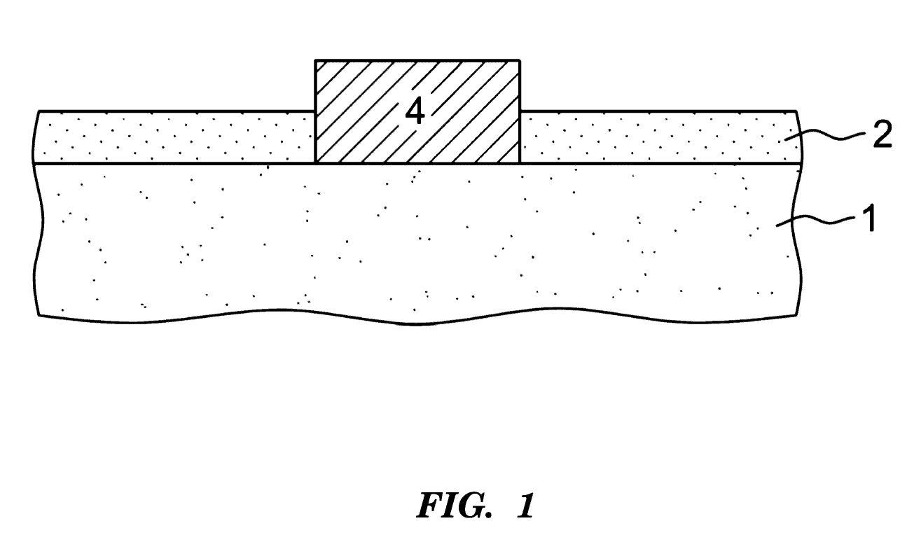

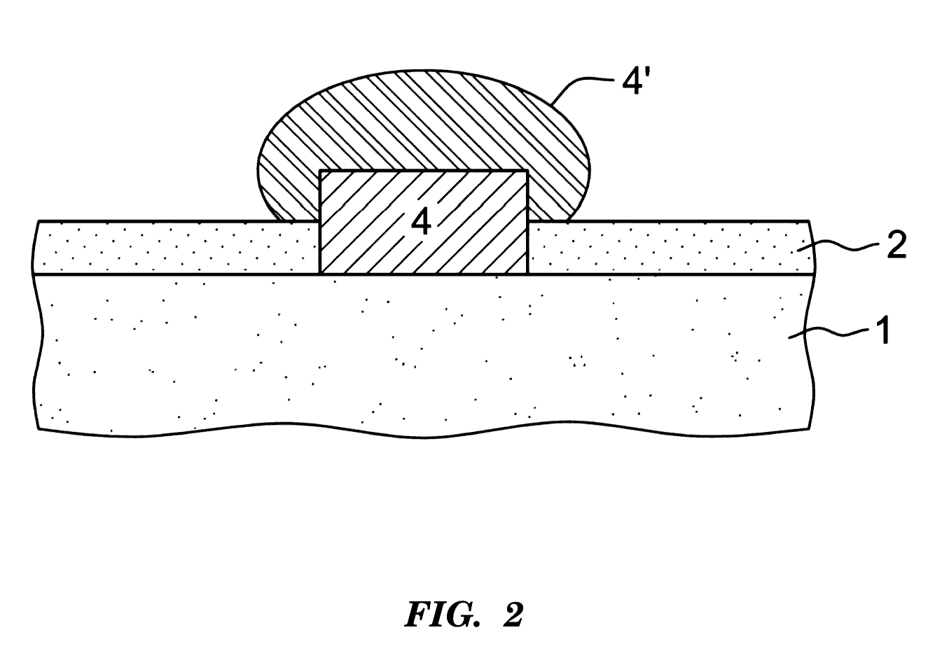

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions, and/or arrangements within the spirit and/or scope of the underlying inventive concepts will be apparent to those skilled in the art from this disclosure.

The disclosed embodiments are directed to photovoltaic devices, including photovoltaic cells and modules containing a plurality of photovoltaic cells, and method for their manufacture. The photovoltaic cells can be used as monofacial cells which receive light at one surface or as bifacial cells which can receive light from the one surface and from an opposite surface.

An important parameter which affects the efficiency and output of a solar cell is an amount of area on a light-incident surface of the solar cell which is covered (directly) or shaded (by an angle of incident sunlight) by electrodes which are required to collect and move electrical current which is generated by the solar cells. The covered area and shading from electrodes may be reduced by decreasing the size of the electrodes. For example, electrodes are often formed as fingers, and decreasing the width of the electrode fingers increases the photoactive area available on the device for receiving and converting incident light.

In one example, conventional solar cell production may use screen printing technology to print electrodes on a front surface of a photovoltaic device with such a technique often using a metal paste (e.g., silver paste). This technique may result in a comparatively broad electrode line width (e.g., in excess of 50 μm (typically about 100 μm)), and a fairly low line conductivity of the metal grid due to the use of several non-metallic components (e.g., glass frit) in the printed paste. As indicated above, increased line width may result in increased shading and less light falling on the light-incident surface of the solar cell. In addition, a firing process may result in contamination of a substrate of the cell by ingredients of the metal paste, thereby reducing the energy conversion efficiency of the device. Moreover, some metal pastes (e.g., silver) may be comparatively expensive making them unfavorable as a primary electrode material.

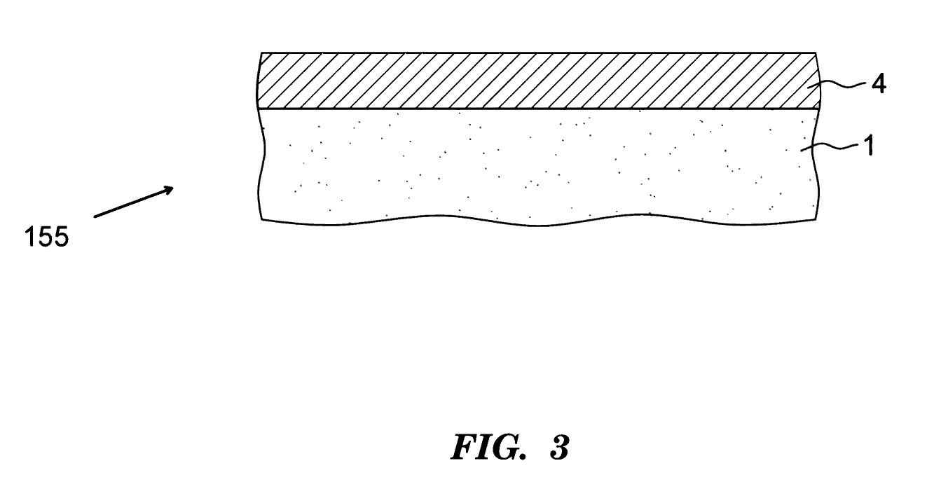

FIGS. 3-11 show an example embodiment of the invention which uses a metal etch resist to form a metal grid pattern for e.g., a solar cell. It is understood that many techniques exist for the formation of a metal patterns on a substrate in accordance with the invention and that the sequence presented is only one possible example.

Initially, a substrate 1 is supplied. This substrate may be a silicon semiconductor wafer of either p or n-type doping. The substrate may be textured, for example with a random pyramid pattern to improve light trapping in the solar cell. The substrate may have dopant diffusions on either or both sides to form emitter structures or surface fields. Such dopant diffusions may be patterned, for example to form so-called selective emitter structures. The substrate may have thin film passivation layers present on either or both surfaces. Such passivation layers may for example consist of doped or intrinsic amorphous silicon layers, silicon dioxide, silicon nitride, doped or intrinsic poly-silicon, doped or intrinsic silicon carbide, aluminum oxide or any of a large variety of such passivation layers and combinations thereof.

A metal film 4 is deposited over a surface of the substrate, and the structure shown in FIG. 3 results, which shows a metal film 4 over substrate 1. Such metal deposition may, for example, be performed using well established techniques such as sputtering, thermal evaporation or e-beam evaporation. It is understood that this metal film may consist of multiple different metal layers where these metal layers are required to perform different functions. For example, a bottom—next to the substrate—metal layer may be required to form good electrical contact and adhesion to the substrate, a top or middle metal layer may be required to act as a diffusion barrier, and a top metal layer may need to function as an electroplating seed. Further, it is understood that the metal film may require specific properties, for example thickness and/or composition.

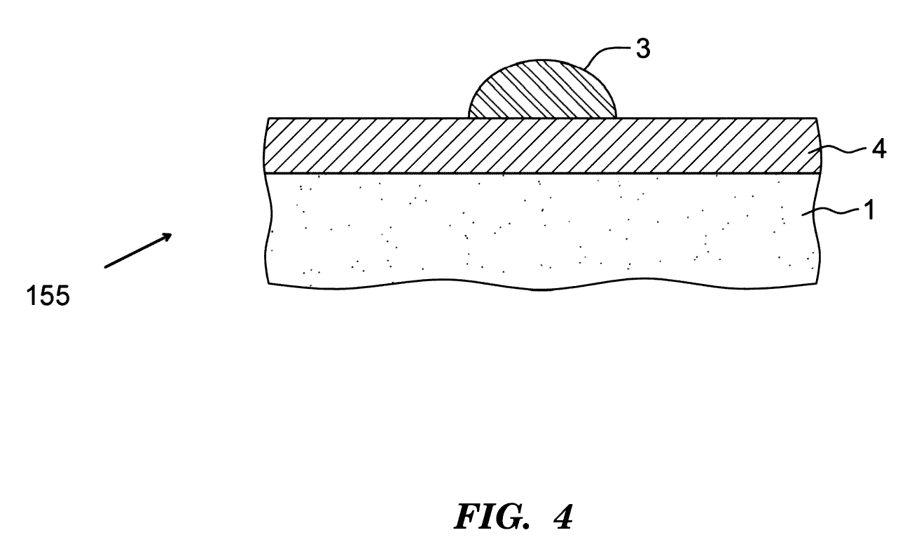

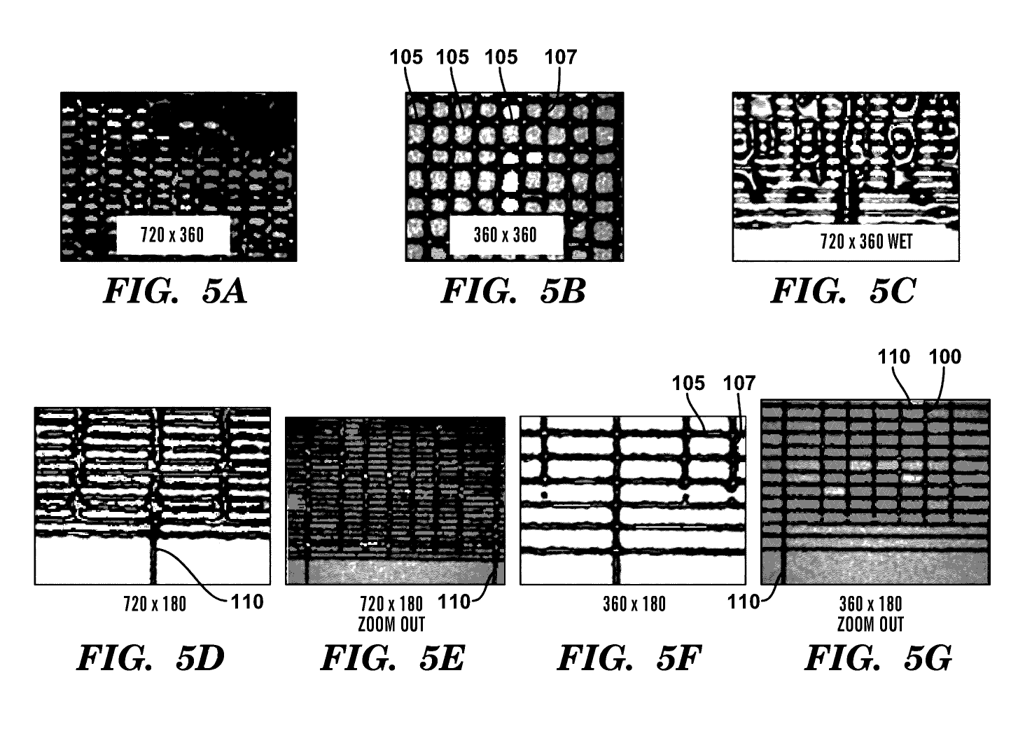

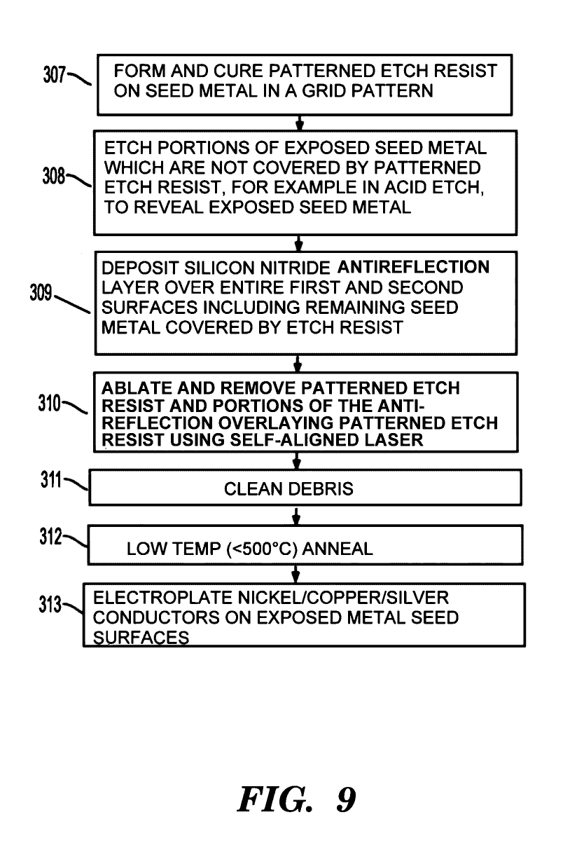

A patterned etch resist 3 (e.g., narrow resist line) may next be formed (e.g., using an ink jet printer) over metal film 4 to form a structure 155 as depicted in FIG. 4 and indicated as Step 307 in FIG. 9. Patterned etch resist 3 may be formed from well-known materials, such as commercially available inkjet printable resists configured to be deposited in a pattern on metal film 4 of structure 155. In one embodiment, a resist pattern may include a pattern for later forming narrow conductive fingers and connective bus bars extending transversely to the fingers. Resist 3 may be configured in a pattern such that the bus bars may be located between the fingers relative to each other. Such bus bars may have a thickness and height about the same relative to each other and relative to the fingers. The resist may have bus bar resist portions 100 and finger resist portions 110 that are aligned about perpendicular to each other. Bus bar portions 100 may include horizontal resist lines 105 and vertical resist lines 107 aligned in a crosshatched or grid pattern as depicted in FIGS. 5A-5G. As depicted in this figure, finger portions 110 may be aligned parallel to vertical resist lines 107. For example, resist 3 may be printed with a resolution of 720×360 dots per inch (dpi), 360×360 dpi, 720×360 dpi, 720×180 dpi, and 360×180 dpi, as depicted in the figure. The dots per inch resolution described may provide an equivalent line per inch resolution for the bus bars and fingers as each dot printed provides a linear portion of such a line. The printing of the resist may be a dry-on-dry printing process or a wet-on-wet process as will be understood by one of ordinary skill in the art. A dry-on-dry printing process may provide better results in printing a resist (e.g., resist 3) in accordance with the present invention due to increased control (i.e., less line width blowout) of a width of a line (e.g., resist 3).

The grid or cross-hatching pattern described above enables economical patterning of a resist (e.g., resist 3) utilized to later form a bus bar by using a same features size (i.e., line width) as utilized for the fingers, and further the native resolution of a print head (e.g., an IJ print-head) may be utilized. The native resolution of the print head used may be 360 dpi, for example. Other print heads with different resolutions may also be used. Further, a pitch between nozzles of a print head (e.g., an IJ print-head) could be 70.5 μm, for example. Printed features are advantageously an integer multiple/fraction of a native resolution. For example, a resolution of 360 dpi may provide twice the resolution or 720 dpi. In another example, one half a resolution of 360 dpi may provide 180 dpi. A finger pitch may also be a multiple of a native resolution, such as 1/16 of 360 dpi=22.5 dpi=1128 μm.

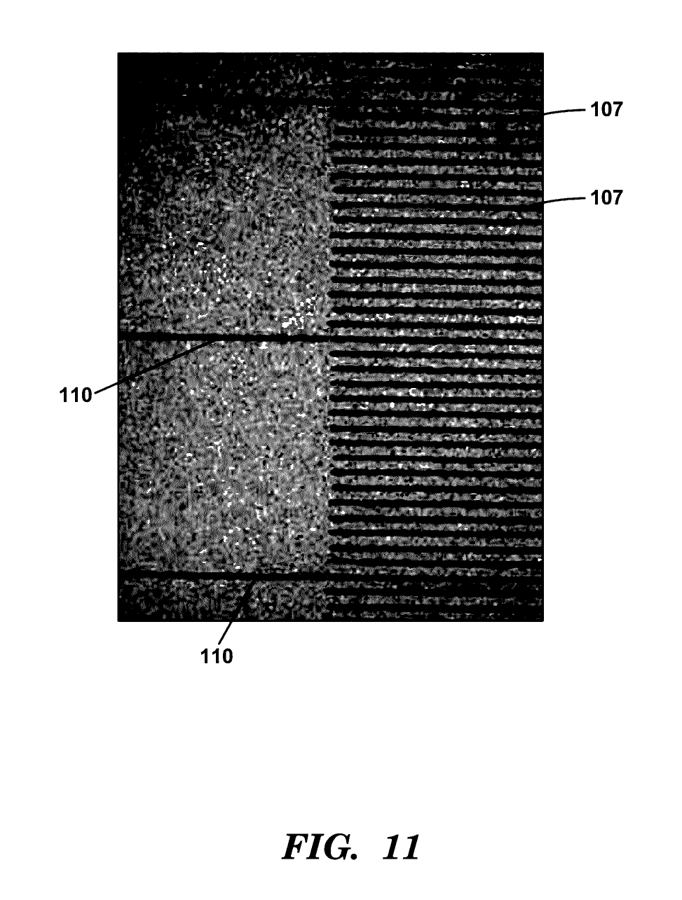

In an example of printing a resist for a bus bar (e.g., at a resolution of 360 dpi×360 dpi) a first step would be to print a resist for fingers (e.g., finger resist portions 110) and a part (e.g., vertical resist lines 107) of a cross hatched bus bar. In an example where the bus-bar dpi is equal or less than a native dpi of the print head, the necessary printing of the resist may be done in a minimum of two passes for dry-on-dry printing and in one pass for wet-on-wet printing. As depicted in FIG. 11, resist finger portions (e.g., finger portions 110) may be aligned parallel to bus bar resist vertical portions (e.g., vertical resist lines 107).

In a second step, the print-heads or substrate (e.g., substrate 1) may then be rotated 90 degrees followed by printing perpendicular features, such as bus bar resist horizontal portions (e.g., horizontal resist lines 105), being printed to result in a crosshatched pattern as depicted in the various examples of FIGS. 5A-5G. Each of these printing processes may be performed in one or two passes depending upon whether wet (i.e., one pass) or dry (i.e., two passes) are utilized. FIGS. 5A-5G depict examples of resists for bus bars and fingers at various resolutions, as described above.

In one example, resist 3 may be a UV curable black or other pigmented ink resist which may absorb the wavelength of a high intensity light source, such as a laser light source. Before applying resist 3 (e.g., via printing), structure 155 depicted in FIG. 3 may be pretreated to reduce the surface energy of the metal film 4, making it a more hydrophobic surface. Such pretreatment lowers the surface energy of metal film 4, helping to ensure that when the resist is applied (e.g., printed) the resist beads up on metal film 4 and does not spread out thereby reducing the printed feature size. The pretreatment may include a deposition of a monomer with a hydrophobic group with reactive chains which attach to a surface of metal film 4. Alternatively, a plasma treatment may be used for such pretreatment, or a monomer layer of molecules may be deposited as the surface treatment. In short, any surface treatment of metal film 4 which makes the surface hydrophobic (or reduces surface energy) or otherwise inhibits flow of a resist (e.g., resist 3) on a metal film (e.g., metal film 4) may be used. Resist 3 (FIGS. 3-5) may be formed by any of various well-known techniques. In one embodiment, resist 3 may be formed by inkjet printing as indicated above. In another embodiment, resist 3 may be formed by dispensing, spraying, screen printing or photolithographic techniques.

After resist 3 is printed on metal film 4, resist 3 on metal film 4 may be cured under UV light to pin resist 3 in position on metal film 4. Such UV curing also causes polymerization/crosslinking of monomers, oligomers in such resists, to provide a dry, chemically, thermally or physically stable resist. Depending upon the particular resist material that is selected or used, it could be advantageous to use a low temperature curing process in the range of 70-150 C to drive out residual water, if present, from the resist and promote adhesion to the metal layer. After resist 3 is cured, metal film 4 may be etched. Patterned etch resist 3 protects portions of metal film 4 which are covered by patterned etch resist 3 during exposure of metal film 4 to a suitable metal etch solution, such as an acid solution (e.g., via a suitable metal acid etch solution, in step 308 of FIG. 9).

In another example, a resist (e.g., resist 3) may be printed via a dry on dry process as indicated above. In this process, a series of drops are printed to define an outline of a resist (e.g., horizontal resist line 105) followed by an UV cure as described above. Spaces between the drops are then filled in with a second set of drops from a printhead followed by a second UV cure of the resist. As suggested above, such a process provides better control of a resist line width (i.e., reduced line width blowout which can occur as ink flows prior to the UV pin/cure) as compared to other processes, such as a wet process.

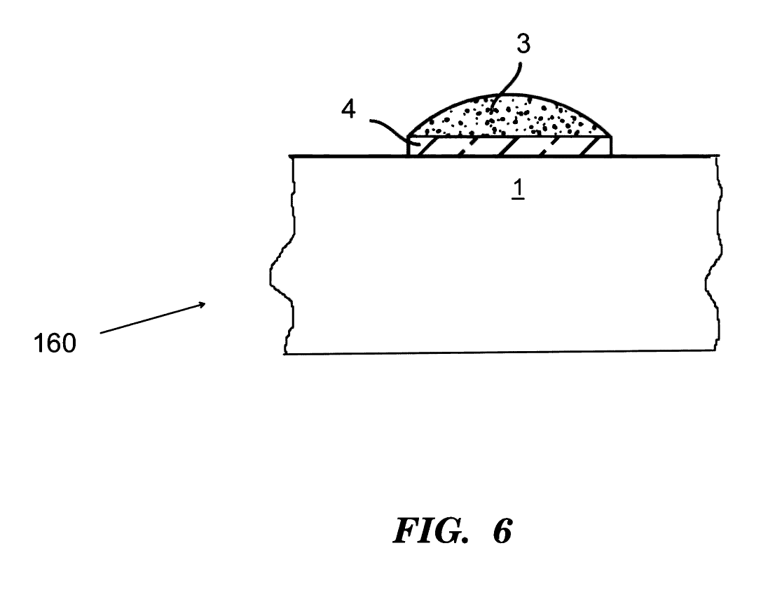

Etching of metal film 4 produces a structure 160, as shown in FIG. 6, which shows no undercutting of metal film 4 beneath the resist. However, depending on the etch conditions, the etching may provide a slight undercutting of metal film 4 beneath resist 3. In an example of metal film 4 being formed of a titanium and nickel/vanadium seed layer a two-step etch can be used. Nitric acid or iron chloride may be used to etch the nickel/vanadium layer and a hydrofluoric acid etch may be used to etch the titanium layer. Other etching solutions may also be used depending on the materials forming the resist (e.g., resist 3) and metal film (e.g, metal film 4).

As described, in contrast to the prior art formation of bus bars, the bus bars of the present invention may be formed in a crosshatched pattern such that portions of each bus bar are spaced from one another unlike the continuous direct printing of the prior art to form a bus bar. In particular, bus bars of the prior art are completely filled in such that no crosshatch pattern or space would exist between printed perpendicular portions thereof in contrast to the description herein. Thus, the same print heads may be used to form the resists for the fingers and bus bars of the present invention since each individual print line (e.g., for both the finger resist portions and bus bar resist portions) have a same width. In contrast to the prior art, in the present invention it would not be necessary to print additional passes relative to those described above to fill in an area occupied by the spaces defined by the crosshatch pattern described above or to utilize additional print heads, such as print heads having larger drop sizes to print wider bus bar lines. Instead, due to the cross hatched pattern of the present invention the same size resist lines may be used from a same print head for both the finger resist portions (e.g., finger resist portions 100) and bus bar resist portions (e.g., bus bar resist portions 110).

Moreover, the crosshatch pattern of the bus bar resists (e.g., bus bar resist portions 110) and resulting bus bars may reduce resist stress associated with a full area bus bar print, as in the prior art, in that such a prior art resist print may result in delamination of a bus bar relative to the fingers prior to a resist strip (e.g., a laser ablation and clean as described in co-owned application Ser. No. 14/707,697, attorney docket number 3304.016). Further, by making the bus bars out of cross-hatched finger-like features process interactions and complications are minimized (e.g., a UV cure, ablation and clean process parameters are essentially identical for the resists finger and the bus resists).

The etching of metal film 4 while resist 3 is present as described provides for an advantageous bus bar formed in a crosshatch or grid pattern with fingers connected to and extending between the bus bars. For example, after etching, bus bar portions of metal film 4 are aligned relative to each other at right angles, and fingers are aligned with a portion of such a pattern (e.g., horizontal bus bar portions formed by horizontal resist lines 105) and perpendicular to another portion (e.g., vertical bus bar portions formed by vertical resist lines 107), as described above relative to resist 3 such that the bus bars have about a same thickness and width relative to the fingers.

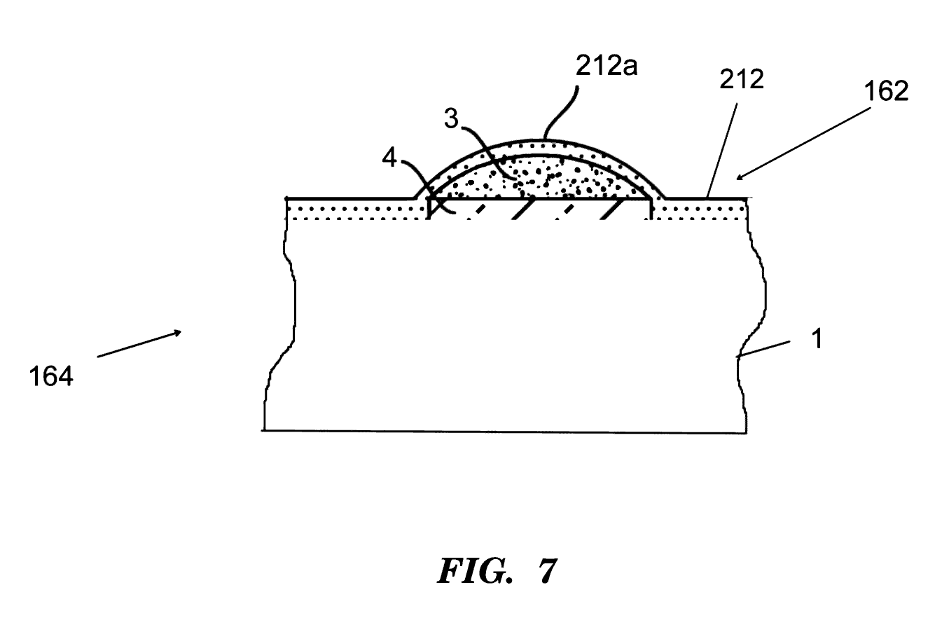

A material layer 212 which functions both as a passivation layer and antireflection coating, may next be formed on a front surface 162 of a structure 164, as depicted in FIG. 7 and indicated in Step 309 of FIG. 9. Alternatively, or additionally, such a material layer (e.g., material layer 212) could be formed on surface 162 and a back surface (not shown) of substrate 1. The material layer could be formed of any dielectric material which has optical properties of an anti-reflective coating and can passivate surface 162 and may, for example, be deposited using PECVD. As also shown in FIG. 7, material layer 212 (e.g., a dual-function passivation/antireflection layer) is deposited over any exposed etch resist (e.g., etch resist 3) and over substrate 1. Although FIG. 7 is not to scale and enlarged for clarity, it is understood that material layer 212 coats textured surfaces of substrate 1 while maintaining the texture features, i.e., material layer 212 conforms to the substrate 1 texture. Material layer 212 could be formed of silicon nitride which would allow the layer to act as a passivation layer and antireflection coating. Further, material layer 212 may also be formed of an undoped layer of silicon carbide (e.g., as an anti-reflection coating and as a passivation layer). In another embodiment (not shown), a material layer may be applied as described above but which would not perform both antireflection and passivating functions. For example, titanium oxide may be utilized as such a layer which provides an anti-reflection coating only.

After material layer 212 is applied, etch resist 3 and a portion 212a (FIG. 7) of material layer 212 over etch resist 3 may be removed as indicated in Step 310 of FIG. 9. Such removal may be performed via any of various methods which breaks, dissociates, or otherwise allows portion 212a and a portion of resist 3 to be removed from a surface 264 of metal film 4.

In one example, the described removal may be accomplished with a high intensity light source, such as a laser, as described in co-owned application Ser. No. 14/707,697 (Attorney Docket No. 3304.016) shown in FIG. 7. Further, although the process is described relative to structure 155, the process of forming a metal film (e.g., metal film 4), forming an etch resist (e.g., etch resist 3) on the metal film, forming a dielectric layer (e.g., material layer 212 forming an antireflection and/or passivation layers) and removing a portion of the resist may also be utilized on other solar cell structures having substrates formed differently than that described relative to structure 155.

Any debris associated with the breakdown of resist 3 and overlying portion 212a of material layer 212 may be removed for example, by blowing any debris away using a suitable blower as indicated, for example, in Step 311 of FIG. 9. A water-based detergent or solvent-based spray may optionally further be used to clean such debris from a breakdown of resist 3 of structure 164.

Following the cleaning of structure 164 described above, a low temperature anneal may be conducted with a relatively low temperature of less than or about 500° C. to promote adhesion of metal film 4 to substrate 1 and a good electrical contact as indicated in Step 312 of FIG. 9. This anneal can be done, for example, in a temperature range of about 250° C. to about 500° C. As one specific example, the anneal can be accomplished at a temperature of about 375° C. for about 2 minutes. This low temperature anneal can also reduce defect damage to the semiconductor layers of substrate 1 which may have occurred during deposition of metal film 4. The anneal may be conducted in an atmosphere having a very low concentration of oxygen to avoid oxidation of surface 264 which might make it hard to later electroplate. Typically, the atmosphere will contain less than 100 ppm of oxygen, and preferably less than 20 ppm of oxygen. The anneal atmosphere can be a nitrogen atmosphere (N₂) with a small amount of a forming gas, such as hydrogen. The forming gas utilized may be dependent upon a type of material/metal being used (e.g., metal film 4) to avoid oxidation or other un-desirable characteristics of such material/metal. The forming gas may be in a concentration of about 0 to about 5% by volume, for example, 4%. The forming gas may further help reduce oxidation of surface 264.

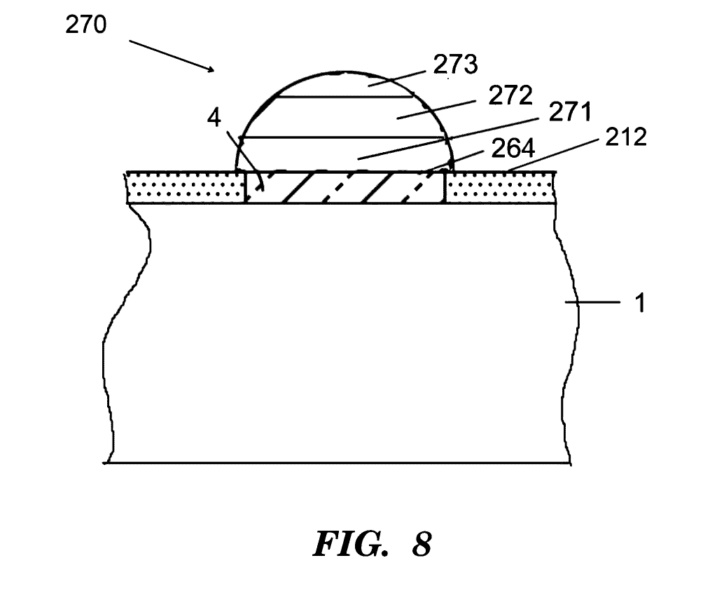

As shown in FIG. 8, a conductor 270 may next be formed on metal surface 264 (of metal film 4). Conductor 270 may be formed from one or a plurality of conductive materials, for example metals such as nickel, copper, silver, titanium, vanadium, tin or any combination thereof. The conductor may be applied to surface 264.

In one embodiment, conductor 270 may be comprised of a metal stack consisting of a layer of nickel 271 applied to surface 264, a layer of copper 272 applied to the layer of nickel 271, and a layer of silver 273 applied to the layer of copper 272 as indicated, for example in FIG. 8 with the plating of the metals shown in simplified form. Conductor 270 may be formed by electroplating on the seed metal surface 264 as indicated, in Step 313 of FIG. 9. The electroplating occurs on all exposed metal surfaces (e.g., surface 264) of the metal film 4 (i.e., not on areas of material layer 212). Accordingly, any undercutting of the metal film 4 which may have occurred during etching of the metal film 4 (FIG. 6) described above may be filled during the plating process (not shown). Electroless plating or light induced plating deposition processes may also be used to produce conductors 270.

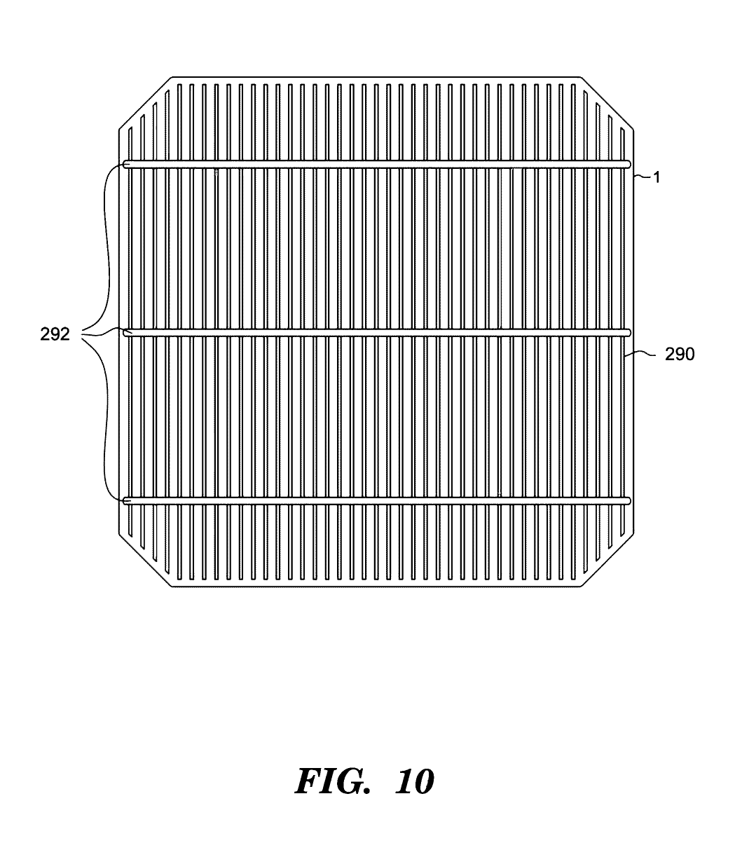

Using the techniques described above, very narrow finger and bus bar conductors may be produced. For example, conductive fingers 290 and bus bars 292 may be formed as described above for conductor 270. As shown in FIG. 10, conductive fingers 290 and transverse bus bars 292 may form lines with a width in a range of about 40 μm to about 60 μm and a height in a range of about 5 μm to about 20 μm and may be spaced on a pitch in a range of about 0.2 mm to about 2.5 mm. Finger conductors 290 and bus bar conductors 292 allow more light into a substrate (e.g., substrate 1) for photo conversion and the short height described reduces shading of light hitting such a substrate. As described above the bus bars and fingers may be formed in a single step by etching after the deposition of a resist. The formation of the bus bars and fingers together eliminates a later step of adding a plurality of bus bars to a plurality of metallic fingers. The elimination of this later bus bar step also eliminates a secondary deposition of a resist which would be undesirable to be present in later processes. For example, a resist as described above could be corrosive if left in place and is better not to be present in other processes, such as PECVD processes.

Further, the use of a laser to strip a resist (e.g., step 310 of a laser ablation and clean as described in co-owned application Ser. No. 14/707,697, (Attorney docket number 3304.016) provides a solvent free strip which reduces costs and the need for solvents in the process thereby reducing the need to handle such solvents and provides environmental benefits. Also, the described process eliminates steps (e.g., application of a separate bus bar resistive portion after the formation of a finger resistive portion due to both portions being formed in a same process) compared to the prior art.

Further, the resist removal technique described (e.g., laser ablation and removal step) allows the use of resists which are compatible with relatively high temperature and/or vacuum based deposition techniques for ARC and/or passivating layers.

Also, the inkjet printing of resists as described is done with a minimum amount of complexity and cost, high throughput patterning, nozzle redundancy with a minimal number of print heads, and contact-less resist application which provides less wafer breakage and micro-cracks.

A number of embodiments have been described and illustrated. Nevertheless, it will be understood that various modifications may be made without departing from the spirit and scope of the invention, which is defined solely by the scope of the appended claims.

1. A method for use in forming a photovoltaic device, comprising:
forming a metal film on the doped semiconductor;
forming a patterned etch resist on the metal film, the resist comprising a plurality of finger portions and a plurality of bus bar portions aligned in a grid pattern; and
etching the metal film to form a pattern of fingers and bus bars according to the resist.

2. The method of claim 1, wherein the plurality of finger portions are aligned substantially perpendicularly to the plurality of bus bar portions.

3. The method of claim 1, wherein the bus bar portions comprise a plurality of horizontal resist lines and a plurality of vertical resist lines aligned in a second grid pattern.

4. The method of claim 3, wherein the plurality of finger portions are substantially aligned with the plurality of horizontal resist lines and are substantially perpendicular to the plurality of vertical resist lines.

5. The method of claim 1, further comprising forming a dielectric layer on the doped semiconductor and the patterned etch resist and subsequently applying a high intensity light source having a wavelength which is transmitted through the dielectric layer and absorbed by the patterned etch resist, to remove the patterned etch resist.

6. The method of claim 5 wherein the high intensity light source comprises a laser.

7. The method of claim 5, wherein applying the high intensity light source to remove the patterned resist results in rapid thermal heating of the resist and/or interface between resist and underlying metal film and causes the patterned resist to thermally decompose, crumble, directly ablate, delaminate from the metal film and/or portions of the dielectric layer which are in contact with the patterned etch resist to break apart.

8. The method of claim 7 wherein the high intensity light source comprises a laser.

9. The method of claim 7, wherein patterned resist which has been exposed to a high intensity light source is subsequently removed and the doped semiconductor surface cleaned by a solvent free aqueous based spray or immersion process.

10. The method of claim 1 further comprising pretreating the metal film prior to the forming of the patterned etch resist to make the metal film hydrophobic.

11. The method of claim 1, wherein the forming the etch resist further comprises curing the etch resist to pin the etch resist in a position on the seed metal layer.

12. (canceled)

13. (canceled)

14. (canceled)

15. (canceled)

16. The method of claim 10 wherein an undercut of the metal film during the etching is repaired by an initial plated layer which prevents diffusions of contaminants into the doped semiconductor

17. (canceled)

18. The method of claim 1, wherein the patterned etch resist is formed by inkjet printing.

19. The method of claim 5, wherein the high intensity light source has an emission peak in a wavelength range of 0.5 μm to 11 μm.

20. The method of claim 19, wherein the patterned etch resist, at its maximum thickness and at the light source emission peak wavelength, has an optical transmission of not more than 60%.

21. The method of claim 18, where in the inkjet drop volume is within a range of 0.2 to 60 pL.

22. The method of claim 18, where in the inkjet drop volume is within a range of 0.5 to 6 pL.

23. An assembly for use in forming a photovoltaic device, the assembly comprising:
a metal film on a doped semiconductor;
a patterned etch resist on the metal film, the resist comprising a plurality of finger portions and a plurality of bus bar portions, the bus bar portions comprising a plurality of horizontal resist lines and a plurality of vertical resist lines aligned in a grid pattern.

24. The assembly of claim 23, wherein the plurality of finger portions are aligned substantially perpendicularly to the plurality of bus bar portions.

25. The assembly of claim 23, wherein the plurality of finger portions are substantially aligned with the plurality of horizontal resist lines and are substantially perpendicular to the plurality of vertical resist lines.
